(19) United States
(12) Patent Application Publication
(10) Pub. No.: US 2021/0269713 A1
(43) Pub. Date: Sep. 2, 2021

(54) LUMINESCENT MATERIAL INCLUDING HOLE AND ELECTRON TRAPS AND AN APPARATUS INCLUDING SUCH MATERIAL

(71) Applicant: SAINT-GOBAIN CERAMICS & PLASTICS, INC., Worcester, MA (US)

(72) Inventor: Peter R. MENGE, Novelty, OH (US)

(21) Appl. No.: 17/256,429

(22) PCT Filed: Jun. 21, 2019
(86) PCT No.: PCT/US2019/038504

§ 371 Date: Dec. 28, 2020

Related U.S. Application Data
(60) Provisional application No. 62/691,649, filed on Jun. 29, 2018.

(51) Int. Cl. C09K 11/77; C30B 29/12; C30B 15/14; C30B 11/00; G03F 1/48

(52) U.S. Cl. CPC C09K 11/7706; C09K 11/7712; C30B 29/12; G01T 1/2023; C30B 11/003; G03F 1/48; C30B 15/14

(57) ABSTRACT

A luminescent material can include an element or an interstitial site that provides a hole trap in the luminescent material; a first dopant that provides a first electron trap in the luminescent material; and a second dopant that provides a second electron trap in the luminescent material, wherein the second dopant is a relatively shallower electron trap as compared to the first dopant. In an embodiment, a ratio of the first dopant to the second dopant is in a range of 10:1 to 100:1 on an atomic basis. In another embodiment, a ratio of the first dopant to the second dopant is selected so that luminescent material has a lower average value for a departure from perfect linearity in a range of 5 keV to 20 keV that is less to other luminescent materials of the same base compound. The luminescent material may not be a rare earth halide.

### TECHNICAL FIELD

The present disclosure is directed to luminescent materials and apparatuses using the same, and more particularly to luminescent materials including hole and electron traps and apparatuses including such luminescent materials.

### BACKGROUND ART

A luminescent material can be co-doped to improve performance such as increased light output, lower energy resolution, less departure from perfect proportionality, or the like. In many instances, the co-doping includes a scintillating activator and one other dopant. Such co-doping may not optimize performance of the luminescent material. Further improvements with luminescent materials are desired.

### BRIEF DESCRIPTION OF THE DRAWINGS

Embodiments are illustrated by way of example and are not limited in the accompanying figures.

FIG. 1 includes an illustration of a radiation detection apparatus in accordance with an embodiment that can be used in medical imaging.

FIGS. 2 and 3 include illustrations of a radiation detection apparatus in accordance with an embodiment that can be used in drilling or well logging.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION OF THE PREFERRED EMBODIMENT(S)

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

The term “avalanche photodiode” refers to a single photodiode having a light-receiving area of least 1 mm² and is operated in a proportional mode.

The term “SiPM” is intended to mean a photomultiplier that includes a plurality of photodiodes, wherein each of the photodiodes have a cell size less than 1 mm², and the photodiodes are operated in Geiger mode. The semiconductor material for the diodes in the SiPM can include silicon, a compound semiconductor, or another semiconductor material.

The term “principal constituent,” when referring to a particular element within a compound, is intended to that the element is present as part of the molecular formula for the compound, as opposed to a dopant. A dopant within a compound is typically present at a concentration no greater than 5% atomic. As an example, Ce-doped LaBr₃ (LaBr₃:Ce) includes La and Br are principal constituents of the base compound, LaBr₃, and Ce is a dopant and not a principal constituent when Ce is 2% atomic of the cation content of the compound.

The term “rare earth” or “rare earth element” is intended to mean Y, La, and the Lanthanides (Ce to Lu) in the Periodic Table of the Elements. In chemical formulas, a rare earth element will be represented by “RE.”

The term “rare earth halide” is intended to mean a compound having a general chemical formula of REX_{z}, wherein RE is one or more rare earth elements, X is one or more halides, and Z is a value of 2 to 4. The rare earth halides may include one or more dopants. Rare earth halides do not include other compounds that contain one or more non-rare earth elements as part of a principal constituent of such other compound. Exemplary compounds that are not rare earth halides include one or more of a Group 1, Group 2 or, Group 13 element, in addition to a rare earth element. An elpasolite is an example of a compound that is not a rare earth halide.

As used herein, the terms “comprises,” “comprising,” “includes,” “including,” “has,” “having,” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

The use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the arts of luminescent materials and apparatuses including luminescent materials.

The luminescent material can have better linearity as compared another luminescent material that has a hole trap and only one electron trap. Linearity refers to how well a luminescent material approaches perfect linear proportionality between gamma ray energy and light output. The linearity can be measured as a departure from perfect linearity. A luminescent material having perfect linearity would always create the same number of photons per unit energy absorbed, regardless of the energy of the gamma ray. Thus, its departure from perfect linearity is zero.

The departure from perfect linearity is more significant at lower energies than it is for higher energies. A higher energy gamma ray (for example, greater than 2000 keV) may enter the luminescent material, which in turn, may generate several lower energy gamma rays (for example, less than 50 keV). If the luminescent material generates less scintillating light for lower energy gamma rays, the luminescent material has poor linearity. Thus, the response of the luminescent material to gamma rays at lower energies, such as less than 50 keV, can be more significant to linearity than the response at higher gamma ray energies.

Departure from perfect linearity can be determined as follows. Data for responses to different gamma ray energies are collected over a range of gamma ray energies. For example, the range of gamma ray energies can be from 5 keV to 20 keV. After reading this specification, skilled artisans will be able to select an energy range for their particular application.

After the data is collected, using a least squares fit, a linear equation is generated having an equation of:

E_{calc}=m*PH Equation 1

where:

E_{calc} is the calculated energy;

PH is the pulse height (light output); and

m is the slope of the line (fit coefficient).

Note that the line passes through the point (0,0) corresponding to a pulse height of zero (no light output) when the energy is zero. Thus, there is no y-axis offset when the line corresponds to perfect linearity. For a particular gamma ray energy, the departure from perfect linearity (“DFPL”) is determined by the following equation.

DFPL=((E_{calc}−E_{actual})/E_{actual})*100% Equation 2

where E_{actual} is the actual gamma ray energy corresponding to light output and E_{calc} is calculated using Equation 1.

For a set of DFPL data points, an average value, a largest positive deviation, a largest negative deviation, a maximum deviation, an absolute value of any of the foregoing, or any combination thereof can be obtained. In a particular embodiment, the average DFPL can be determined using an integral in accordance with Equation 3 below.

$$DFP {L}_{a v erage} = \frac{{{\int }^{{E}_{upper}}}_{{E}_{lower}} DFPL ( {E}_{i} ) \cdot {dE}_{i}}{{E}_{upper} - {E}_{lower}} \qquad Equation 3$$

where

DFPL(Ei) is DFPL at energy Eᵢ;

Eᵤₚₚₑᵣ is the upper limit of the energy range; and

E_{lower} is the lower limit of the energy range.

In the luminescent material, an element or an interstitial site can be a hole trap within the luminescent material. The element may be an element that is a principal constituent of a base compound that makes up the luminescent material or may be a dopant.

Different dopants can provide electron traps. As compared to a relatively shallower electron trap, more energy is required for a relatively deeper electron trap to release an electron and for such electron to reach the minimum energy level of the conduction band of the base compound (without dopants) of the luminescent material. As used herein, the bandgap energy and conduction band are for the undoped base compound by itself, as opposed to such compound when in contact with a dissimilar material (due to potential band bending).

A ratio of the dopants can be selected in an amount such that performance is improved as compared to only one of the dopants being present. In an embodiment, one of the dopants may provide a relatively shallower electron trap as compared to the other dopant. As used herein, the depth of an electron trap is determined by the difference in energy between the minimum energy of the conduction band of the undoped base compound of the luminescent material and the ionization energy of the dopant within such luminescent material. A relatively shallower electron trap may have an energy difference of at most 0.3 eV, and a relatively deeper electron trap may have an energy difference of greater than 0.3 eV. As used herein, the dopant that provides the relatively deeper electron trap is referred to as “DET”, and the dopant that provides the relatively shallower electron trap is referred to as “SET”. On a relative basis, the energy level difference between a minimum energy level of a conduction band of the base compound and an ionization energy of the SET is at most 10% of the bandgap energy, and the energy level difference between a minimum energy level of a conduction band of the base compound and an ionization energy of the DET is greater than 10% of the bandgap energy.

In a luminescent material, the DET may cause a negative departure from perfect linearity, and the SET may cause a positive departure from perfect linearity. A proper combination of dopants corresponding to the DET and SET can help to reduce the departure from perfect linearity over a desired energy range as compared to having only a DET or only a SET, or if the DET and SET are present in an improper amount.

The ratio of the concentrations of the dopants for the electron traps may be selected, so that the number of electrons having sufficient energy to reach the conduction band of the base compound from each of the DET and SET are similar. In an embodiment, the concentration of the DET is greater than the concentration of the SET, as the relatively deeper electron traps relinquish electrons less readily than the relatively shallower electron traps. In an embodiment, the ratio of the DET to the SET is in a range of 10:1 to 100:1 on an atomic basis.

For a particular DET, the ratio of the concentrations of the DET:SET increases as the energy level difference between the minimum energy level of the conduction band and the ionization energy of the DET increases. For example, one DET may have an energy level difference of 0.7 eV, and another DET may have an energy level difference of 1.1 eV. The ratio of the relatively DET:SET will be lower for the DET with the energy level difference of 0.7 eV and will be higher for the other DET with the energy level difference of 1.1 eV.

In an embodiment, the ratio of the DET:SET is at least 15:1, at least 20:1, or at least 30:1, and in another embodiment, the ratio of the DET:SET is at most 95:1, at most 80:1, or at most 70:1. In a particular embodiment, the ratio of the DET:SET is in a range of 15:1 to 95:1, 20:1 to 80:1, or 30:1 to 70:1.

In general, Group 1, Group 2, rare earth elements, and Bi may be any one or more of a hole trap, a DET, or a SET. The particular function of the foregoing elements may depend on the composition of the base compound, the activator, and another dopant present. Targeted radiation can be absorbed by the luminescent material, and in response, an electron can be ejected from the activator. Thus, an activator can provide hole traps during the scintillation process. In an embodiment, the activator can be Ce, Pr, Sm, or Tb. However, in another embodiment, Ce, Pr, Sm, or Tb may not be an activator and may be a DET or a SET. In another embodiment, Eu or Yt may be an activator and used as a hole trap. In still another embodiment, Eu or Yt may be a DET or a SET. In a further embodiment, Bi may be present as a hole trap, a DET, or a SET. Ca or Sr may be a SET, and many of the Group 1 elements (for example, Li, Na, Cs), Mg, Ba, and rare earth elements, when not hole traps, can be a DET.

Thus, depending the principal constituents within a base compound of a luminescent material and dopants selected, a particular element can provide hole traps in one luminescent material, can be a DET in another luminescent material, or may be a SET when the base compound or another dopant is changed. After reading this specification, skilled artisans will be able to determine the hole traps for the luminescent material, select a DET and a SET, and set a DET:SET ratio for the luminescent material to achieve the needs or desires for a particular application.

The concepts as described herein are applicable to a many different luminescent materials. Many different formulas for luminescent materials are provided herein. Particular notations are used particular types of elements. For example, RE can be used to represent a single rare earth element or a combination of rare earth elements, and Ln can be used to represent a single rare earth element or a combination of rare earth elements that is different from RE. M can be used to represent a single metal element or a combination of metal elements. In any of the formulas below, HT represents a hole trap, DET represents a relatively deep electron trop, and SET represents a relatively shallow electron trap.

In an embodiment, the luminescent material can be a metal-silicon-oxygen compound. The metal-silicon-oxygen compound may be a metal oxyorthosilicate, a metal pyrosilicate, or the like. The luminescent material can be a mixed metal oxyorthosilicate or pyrosilicate, wherein the metal oxyorthosilicate or pyrosilicate includes a combination of metals as principal constituents. In an embodiment, the luminescent material can be a Group 2 metal oxyorthosilicate or a Group 2 pyrosilicate or a rare earth metal oxyorthosilicate or rare earth metal pyrosilicate.

RE_{(2-2x-2y-2z)}HT₂ₓ DET_{2y}SET_{2z}SiO₍₃₊₂ₚ₎ (Formula 1)

wherein:

RE is one or more rare earth elements,

HT is an element that provides a hole trap,

DET is a dopant that provides a relatively deep electron trap,

SET is a dopant that provides a relatively shallow electron trap,

each of 2x, 2y, and 2z is at least 0.00001 and at most 0.09, and

p equals 1 (orthosilicate) or 2 (pyrosilicate).

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

The concepts as described herein are particularly suitable for reducing the afterglow of compositions of lutetium orthosilicate (namely LSO) and lutetium yttrium orthosilicate (namely LYSO). Such compositions when doped with cerium may have the formula:

Lu_{(2-2w-2x-2y-2z)}Y_{2w}Ce₂ₓDET_{2y}SET_{2z}SiO₅ (Formula 2)

wherein:

Ce is an element that provides a hole trap,

DET is a Group 1 element, a Group 2 element other than Ca or Sr, or Bi, and

SET is Ca or Sr.

The subscript 2w can be greater than 0 and may be at most 0.3. The subscripts 2x, 2y, and 2z can have any of the values are previously described with respect to Formula 1.

In other embodiments, the scintillation composition can include another metal-silicon-oxygen compound. Exemplary, non-limiting formulas are provided below.

M¹⁺RE_{(1-x-y-z)}HTₓ DET_{y}SET_{z}SiO₄ (Formula 3)

wherein:

wherein:

M¹⁺ is a monovalent element, such as Li, Na, or Cs,

RE is one or more rare earth elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(2-2y-2z)}DET_{2y}SET_{2z}Si₍₁₋ₓ₎HTₓO₃ (Formula 4)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 2x, 2y, and z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

M²⁺_{(1-y-z)}DET_{y}SET_{z}Si₍₁₋ₓ₎HTₓO₃ (Formula 5)

wherein:

M²⁺ is one or more divalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(1-y-z)}DET_{y}SET_{z}Si₂₍₁₋ₓ₎HTₓO₅: (Formula 6)

wherein:

M²⁺ is one or more divalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(3-3y-3z)}DET_{3y}SET_{3z}Si₍₂₋₂ₓ₎HT₂ₓO₇ (Formula 7)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 2x, 3y, and 3z is at least 0.00001 and at most 0.09.

In an embodiment, each of 2x, 3y, and 3z has a value of at least 0.0002, at least 0.0005, or at least 0.001, and in another embodiment, each of 2x, 3y, and 3z has a value of at most 0.05, at most 0.04, or at most 0.03.

M²⁺_{(2-2y-2z)}DET_{2y}SET_{2z}Si₍₃₋₃ₓ₎HT₃ₓO₈: (Formula 8)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 3x, 2y, and 2z is at least 0.00001 and at most 0.09.

In an embodiment, each of 3x, 2y, and 2z has a value of at least 0.0002, at least 0.0005, or at least 0.001, and in another embodiment, each of 3x, 2y, and 2z has a value of at most 0.05, at most 0.04, or at most 0.03.

M²⁺_{(5-5y-5z)}DET_{5y}SET_{5z}Si₍₈₋₈ₓ₎HT₈ₓO₂₁ (Formula 9)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 8x, 5y, and 5z is at least 0.00001 and at most 0.09.

In an embodiment, each of 8x, 5y, and 5z has a value of at least 0.0002, at least 0.0005, or at least 0.001, and in another embodiment, each of 8x, 5y, and 5z has a value of at most 0.05, at most 0.04, or at most 0.03.

M1¹⁺_{(2-2y)}DET_{2y}M2²⁺_{(1-z)}SET_{z}Si₍₁₋ₓ₎HTₓO₄ (Formula 10)

wherein:

M1¹⁺ is a monovalent element,

M2²⁺ is one or more divalent metal elements,

HT is an element that provides a hole trap,

DET is a dopant that provides a relatively deep electron trap,

SET is a dopant that provides a relatively shallow electron trap, and

each of x, 2y, and z is at least 0.00001 and at most 0.09.

In an embodiment, each of x, 2y, and z has a value of at least 0.0002, at least 0.0005, or at least 0.001, and in another embodiment, each of x, 2y, and z has a value of at most 0.05, at most 0.04, or at most 0.03.

Exemplary base compounds include Ba₂MgSi₂O₇, Ba₂Si₃O₈, Ba₂SiO, Ba₂ZnSi₂O₇, Ba₅Si₈O₂₁, BaSi₂O₅, BaSiO₃, Gd₂Si₂O₇, Li₂CaSiO₄, Lu₍₂₋₂ₓ₎Gd₍₂₋ₓ₎SiO₅, Lu₍₂₋₂ₓ₎Y₂ₓSiO₅, Lu₂Si₂O₇, MgSr₂Si₂O₇, NaLaSiO₄, Y₂SiO₅, and the like, wherein x can range from 0 to 1. Each of the foregoing compounds may include a further dopant that is not provided with the chemical formula.

In still another embodiment, the luminescent material can be a metal oxide. The luminescent material can be a single metal oxide, such as a trivalent metal oxide, or a mixed metal oxide, wherein the metal oxide includes a combination of metals as principal constituents. For example, the mixed metal oxide can be a divalent metal-tetravalent metal oxide, a rare earth aluminate, or a rare earth-divalent metal aluminum garnet.

Below are non-limiting, exemplary formulas for families of compounds.

M³⁺_{(2-2x-2y-2z)}HT₂ₓ DET_{2y}SET_{2z}O₃ (Formula 11)

wherein:

M³⁺ is one or more trivalent metal elements,

HT is an element that provides a hole trap,

DET is a dopant that provides a relatively deep electron trap,

SET is a dopant that provides a relatively shallow electron trap, and

each of 2x, 2y, and 2z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

M³⁺_{(8-8x-8y-8z)}HT₈ₓ DET_{8y}SET_{8z}O₁₂ (Formula 12)

wherein:

M³⁺ is one or more trivalent metal elements,

HT is an element that provides a hole trap,

DET is a dopant that provides a relatively deep electron trap,

SET is a dopant that provides a relatively shallow electron trap, and

each of 8x, 8y, and 8z is at least 0.00001 and at most 0.09.

In an embodiment, each of 8x, 8y, and 8z has a value of at least 0.0002, at least 0.0005, or at least 0.001, and in another embodiment, each of 8x, 8y, and 8z has a value of at most 0.05, at most 0.04, or at most 0.03.

M1²⁺_{(1-y-z)}DET_{y}SET_{z}M2⁴⁺₍₁₋ₓ₎HTₓO₃ (Formula 13)

wherein:

M1²⁺ is one or more divalent metal elements,

M2⁴⁺ is one or more tetravalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1²⁺_{(1-y-z)}DET_{y}SET_{z}M2³⁺₍₁₂₋₁₂ₓ₎HT₁₂ₓO₁₉ (Formula 14)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of 12x, y, and z is at least 0.00001 and at most 0.09.

In an embodiment, each of 12 x, y, and z has a value of at least 0.0002, at least 0.0005, or at least 0.001, and in another embodiment, each of 12 x, y, and z has a value of at most 0.05, at most 0.04, or at most 0.03.

M1²⁺_{(2-2y-2z)}DET_{2y}SET_{2z}M2³⁺_{(10-10z)}HT₁₀ₓO₁₇ (Formula 15)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of 10x, 2y, and 2z is at least 0.00001 and at most 0.09.

In an embodiment, each of 10x, 2y, and 2z has a value of at least 0.0002, at least 0.0005, or at least 0.001, and in another embodiment, each of 10x, 2y, and 2z has a value of at most 0.05, at most 0.04, or at most 0.03.

Exemplary compounds that can be modified in accordance with the above-referenced formulas include BaAl₁₀MgO₁₇, BaAl₁₂O₁₉, BaHfO₃, CaHfO₃, Gd₂O₃, Gd₍₃₋₃ₓ₎Y₃ₓAl₅O₁₂, Gd₃Sc₂Al₃O₁₂, Gd₃Y₃Al₁₀O₂₄, GdAlO₃, La₂O₃, LaAlO₃, Lu₂O₃, Lu₃Al₅O₁₂, Lu₃Al₅O₁₂, LuAlO₃, SrHfO₃, Y₂O₃, YAlO₃, or the like, wherein x can range from 0 to 1. Each of the foregoing compounds may include a further dopant that is not provided with the chemical formula.

In yet another embodiment, the luminescent material can be a metal-boron-oxygen compound. The metal-boron-oxygen compound can be a single metal borate or oxyborate or a mixed metal borate or oxyborate, wherein the metal borate or oxyborate includes a combination of metals as principal constituents. In an embodiment, the metal-boron-oxygen compound can be a Group 1-rare earth metal borate, Group 2 metal borate, a Group 2-rare earth metal borate, a Group 2-rare earth metal oxyborate, or a Group 2 metal borooxyhalide.

Below are non-limiting, exemplary formulas for families of compounds.

M²⁺_{(3-3x-3y-3z)}HT₃ₓ DET_{3y}SET_{3z}(BO₃)₃ (Formula 16)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 3x, 3y, and 3z is at least 0.00001 and at most 0.09.

In an embodiment, each of 3x, 3y, and 3z has a value of at least 0.0002, at least 0.0005, or at least 0.001, and in another embodiment, each of 3x, 3y, and 3z has a value of at most 0.05, at most 0.04, or at most 0.03.

M³⁺_{(1-x-y-z)}HTₓ DET_{y}SET_{z}(BO₃)₃ (Formula 17)

wherein:

M³⁺ is one or more trivalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M³⁺_{(1-x-y-z)}HTₓ DET_{y}SET_{z}B₃O₆ (Formula 18)

wherein:

M³⁺ is one or more trivalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M³⁺_{(4-4x-4y)}HT₄ₓ DET_{4y}SET_{4z}B₄O₁₂ (Formula 19)

wherein:

M³⁺ is one or more trivalent metal elements,

HT is an element that provides a hole trap,

DET is a dopant that provides a relatively deep electron trap,

SET is a dopant that provides a relatively shallow electron trap, and

each of 4x, 4y, and 4z is at least 0.00001 and at most 0.09.

In an embodiment, each of 4x, 4y, and 4z has a value of at least 0.0002, at least 0.0005, or at least 0.001, and in another embodiment, each of 4x, 4y, and 4z has a value of at most 0.05, at most 0.04, or at most 0.03.

M²⁺_{(2-2x-2y-2z)}HT₂ₓ DET_{2y}SET_{2z}B₅O₉X (Formula 20)

wherein:

M²⁺ is one or more divalent metal elements;

X is one or more halogens;

HT is an element that provides a hole trap,

DET is a dopant that provides a relatively deep electron trap,

SET is a dopant that provides a relatively shallow electron trap, and

each of 2x, 2y, and 2z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

M1²⁺_{(1-y-z)}DET_{y}SET_{z}M2³⁺₍₁₋ₓ₎HTₓB₇O₁₃ (Formula 21)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1¹⁺₆M2³⁺_{(1-x-y)}RE⁴⁺ₓM3²⁺_{y}(BO₃)₃ (Formula 22)

wherein:

M1¹⁺ is one or more monovalent metal elements;

M2³⁺ is one or more trivalent metal elements, which may or may not include a rare earth element;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1¹⁺₆M2³⁺_{(1-x-y-z)}HTₓ DET_{y}SET_{z}(BO₃)₃ (Formula 23)

wherein:

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1²⁺_{(1-y-z)}DET_{y}SET_{z}M2³⁺₍₁₋ₓ₎HTₓBO₄ (Formula 24)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1²⁺_{(1-y-z)}DET_{y}SET_{z}M2³⁺₍₁₋ₓ₎HTₓB₅O₁₀ (Formula 25)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1²⁺_{(3-3y-3z)}DET_{3y}SET_{3z}M2³⁺₍₁₋ₓ₎HTₓ(BO₃)₃ (Formula 26)

wherein:

M1²⁺ is one or more divalent metal elements;

M2³⁺ is one or more trivalent metal elements,

HT is an element that provides a hole trap,

DET is a dopant that provides a relatively deep electron trap,

SET is a dopant that provides a relatively shallow electron trap, and

each of x, 3y, and 3z is at least 0.00001 and at most 0.09.

In an embodiment, each of x, 3y, and 3z has a value of at least 0.0002, at least 0.0005, or at least 0.001, and in another embodiment, each of x, 3y, and 3z has a value of at most 0.05, at most 0.04, or at most 0.03.

M1²⁺_{(4-4x-4y)}DET_{4y}SET_{4z}M2³⁺₍₁₋ₓ₎HTₓ(BO₃)₃ (Formula 27)

wherein:

M1²⁺ is one or more divalent metal elements,

M2³⁺ is one or more trivalent metal elements,

HT is an element that provides a hole trap,

DET is a dopant that provides a relatively deep electron trap,

SET is a dopant that provides a relatively shallow electron trap, and

each of x, 4y, and 4z is at least 0.00001 and at most 0.09.

In an embodiment, each of x, 4y, and 4z has a value of at least 0.0002, at least 0.0005, or at least 0.001, and in another embodiment, each of x, 4y, and 4z has a value of at most 0.05, at most 0.04, or at most 0.03.

Exemplary compounds that can be modified in accordance with the above-referenced formulas include Ba₂B₅O₉Cl, Ba₂Ca(BO₃)₂, Ba₃Gd(BO₃)₃, Ca₄YO(BO₃)₃, CaLaB₇O₁₃, CaYBO₄, GdB₃O₆, GdBO₃, LaB₃O₆, LaBO₃, LaMgB₅O₁₀, Li₆Gd(BO₃)₃, Li₆Y(BO₃)₃, LuBO₃, ScBO₃, YAl₃B₄O₁₂, YBO₃, or the like. Each of the foregoing compounds may include a further dopant that is not provided with the chemical formula.

In a further embodiment, the luminescent material can be a metal-phosphorus-oxygen compound. The metal-phosphorus-oxygen compound can be a metal phosphite or a metal phosphate. The metal metal-phosphorus-oxygen can be a single metal phosphite or phosphate or a mixed metal phosphite or phosphate, wherein the metal phosphite or phosphate includes a combination of metals as principal constituents. In an embodiment, the metal-phosphorous compound can include as a monovalent metal-rare earth metal phosphite, a Group 2-rare earth metal phosphite, a Group 2 metal phosphate, or a Group 2 metal phosphate halide.

Below are non-limiting, exemplary formulas for families of compounds.

M²⁺_{(1-x-y-z)}HTₓ DET_{y}SET_{z}P₂O₆ (Formula 28)

wherein:

M²⁺ is one or more divalent metal elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(2-2x-2y-2z)}HT₂ₓ DET_{2y}SET_{2z}P₂O₇ (Formula 29)

wherein:

M²⁺ is one or more divalent metal elements;

HT is an element that provides a hole trap,

DET is a dopant that provides a relatively deep electron trap,

SET is a dopant that provides a relatively shallow electron trap, and

each of 2x, 2y, and 2z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

M²⁺_{(3-3x-3y-3z)}HT₃ₓ DET_{3y}SET_{3z}P₄O₁₃ (Formula 30)

wherein:

M²⁺ is one or more divalent metal elements;

HT is an element that provides a hole trap,

DET is a dopant that provides a relatively deep electron trap,

SET is a dopant that provides a relatively shallow electron trap, and

each of 3x, 3y, and 3z is at least 0.00001 and at most 0.09.

In an embodiment, each of 3x, 3y, and 3z has a value of at least 0.0002, at least 0.0005, or at least 0.001, and in another embodiment, each of 3x, 3y, and 3z has a value of at most 0.05, at most 0.04, or at most 0.03.

M²⁺_{(3-3x-3y-3z)}HT₃ₓDET_{3y}SET_{3z}(PO₄)₂ (Formula 31)

wherein:

M²⁺ is one or more divalent metal elements;

HT is an element that provides a hole trap,

DET is a dopant that provides a relatively deep electron trap,

SET is a dopant that provides a relatively shallow electron trap, and

each of 3x, 3y, and 3z is at least 0.00001 and at most 0.09.

In an embodiment, each of 3x, 3y, and 3z has a value of at least 0.0002, at least 0.0005, or at least 0.001, and in another embodiment, each of 3x, 3y, and 3z has a value of at most 0.05, at most 0.04, or at most 0.03.

M²⁺_{(5-5x-5y-5z)}HT₅ₓ DET_{5y}SET_{5z}(PO₄)₃X (Formula 32)

wherein:

M²⁺ is one or more divalent metal elements;

X is one or more halogens;

HT is an element that provides a hole trap,

DET is a dopant that provides a relatively deep electron trap,

SET is a dopant that provides a relatively shallow electron trap, and

each of 5x, 5y, and 5z is at least 0.00001 and at most 0.09.

In an embodiment, each of 5x, 5y, and 5z has a value of at least 0.0002, at least 0.0005, or at least 0.001, and in another embodiment, each of 5x, 5y, and 5z has a value of at most 0.05, at most 0.04, or at most 0.03.

M²⁺_{(1-x-y-z)}HTₓ DET_{y}SET_{z}BPO₅ (Formula 33)

wherein:

M²⁺ is one or more divalent metal elements,

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(3-3x-3y-3z)}HT₃ₓDET_{3y}SET_{5z}B(PO₄)₃ (Formula 34)

wherein:

M²⁺ is one or more divalent metal elements,

HT is an element that provides a hole trap,

DET is a dopant that provides a relatively deep electron trap,

SET is a dopant that provides a relatively shallow electron trap, and

each of 3x, 3y, and 3z is at least 0.00001 and at most 0.09.

In an embodiment, each of 3x, 3y, and 3z has a value of at least 0.0002, at least 0.0005, or at least 0.001, and in another embodiment, each of 3x, 3y, and 3z has a value of at most 0.05, at most 0.04, or at most 0.03.

M1¹⁺M2²⁺_{(1-x-y-z)}HTₓ DET_{y}SET_{z}PO₄ (Formula 35)

wherein:

M1¹⁺ is one or more monovalent metal elements,

M2²⁺ is one or more divalent metal elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

RE_{(1-x-y-z)}HTₓ DET_{y}SET_{z}PO₄ (Formula 36)

wherein: deep electron trap,

RE is one or more rare earth elements; shallow electron trap, and

HT is an element that provides a hole trap at most 0.09.

DET is a dopant that provides a relatively a value of at least 0.0002, at least 0.0005, or

SET is a dopant that provides a relatively

each of x, y, and z is at least 0.00001 and

In an embodiment, each of x, y, and z has a value of at least 0.0002, at least 0.0005, or at least 0.001, and in another embodiment, each of x, y, and z has a value of at most 0.05, at most 0.04, or at most 0.03.

RE_{(1-x-y-z)}HTₓDET_{y}SET_{z}P₂O₇ (Formula 37)

wherein:

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or
at least 0.001, and in another embodiment, each of x, y, and z has a value of at most 0.05, at most 0.04, or at most 0.03.

RE_{(1-x-y-z)}HTₓ DET_{y}SET_{z}P₅O₁₄ (Formula 38)

wherein:

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M¹⁺RE_{(1-x-y-z)}HTₓ DET_{y}SET_{z}P₂O₇ (Formula 39)

wherein:

M¹⁺ is a monovalent rare earth element;

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M¹⁺RE_{(1-x-y-z)}HTₓ DET_{y}SET_{z}(PO₃)₄ (Formula 40)

wherein:

M¹⁺ is a monovalent rare earth element;

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M¹⁺RE_{(1-x-y-z)}HTₓ DET_{y}SET_{z}(PO₄)₂ (Formula 41)

wherein:

M¹⁺ is a monovalent rare earth element;

RE is one or more rare earth elements;

HT is an element that provides a hole trap

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

Exemplary compounds that can be modified in accordance with the above-referenced formulas include AgGd(PO₃)₄, Ba₂P₂O₇, Ba₃(PO₄)₂, Ba₃B(PO₄)₃, Ba₃P₄O₁₃, Ba₅(PO₄)₃F, BaKPO₄, BaP₂O₆, Ca₅(PO₄)₃F, CaBPO₅, CeP₅O₁₄, CsGd(PO₃)₄, CsLuP₂O₇, CsYP₂O₇, K₃Lu(PO₄)₂, KGd(PO₃)₄, LuP₂O₇, KYP₂O₇, LiCaPO₄, LiGd(PO₃)₄, LuPO₄, NaBaPO₄, NaGd(PO₃)₄, NaLuP₂O₇, RbLuP₂O₇, RbYP₂O₇, Sr₅(PO₄)₃F, or the like. Each of the foregoing compounds may include a further dopant that is not provided with the chemical formula.

In still a further embodiment, the luminescent material can be a metal-oxygen-sulfur compound. The metal metal-oxygen-sulfur compound can be a single metal oxysulfide or a mixed metal oxysulfide, wherein the metal oxysulfide includes a combination of metals as principal constituents. In an embodiment, the metal-oxygen-sulfur compound can be a metal oxysulfide, such as a rare earth metal oxysulfide.

Below are non-limiting, exemplary formulas for families of compounds.

RE_{(2-2x-2y)}HT₂ₓ DET_{2y}SET_{2z}O₂S (Formula 42)

wherein:

RE is one or more rare earth elements;

HT is an element that provides a hole trap,

DET is a dopant that provides a relatively deep electron trap,

SET is a dopant that provides a relatively shallow electron trap, and

each of 2x, 2y, and 2z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

Exemplary compounds that can be modified in accordance with the above-referenced formulas include Gd₂O₂S, La₂O₂S, or the like. Each of the foregoing compounds may include a further dopant that is not provided with the chemical formula.

In yet a further embodiment, the luminescent material can be a metal-oxygen-halogen compound. The metal metal-oxygen-halogen compound can be a single metal oxysulfide or a mixed metal oxysulfide, wherein the metal oxysulfide includes a combination of metals as principal constituents. In an embodiment, the metal-oxygen-halogen compound can be a metal oxyhalide, such as a rare earth metal oxyhalide.

Below are non-limiting, exemplary formulas for families of compounds.

RE_{(1-x-y-z)}HTₓ DET_{y}SET_{z}OX (Formula 43)

wherein:

RE is one or more rare earth elements;

X is one or more halogens;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

Exemplary compounds that can be modified in accordance with the above-referenced formulas include GdOBr, GdOCl, GdOF, GdOI, LaOBr, LaOCl, LaOF, LaOI, LuOBr, LuOCl, LuOF, LuOl, YOBr, YOCl, YOF, or the like. Each of the foregoing compounds may include a further dopant that is not provided with the chemical formula.

In another embodiment, the luminescent material can be a metal halide that includes a Group 1, Group 2, or Group 13 element. The luminescent material can be a mixed metal halide, wherein the mixed metal halide includes a combination of metals as principal constituents. In an embodiment, the mixed metal halide can include a Group 1-rare earth metal halide, a Group 2-rare earth metal halide, or the like.

Below are non-limiting, exemplary formulas for families of compounds.

M²⁺_{(1-x-y-z)}HTₓ DET_{y}SET_{z}X₂ (Formula 44)

wherein:

M²⁺ is a divalent metal element;

X is one or more halogens;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M¹⁺HTₓ DET_{y}SET_{z}X (Formula 45)

wherein:

M¹⁺ is one or more monovalent metal elements;

X is one or more halogens;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1²⁺_{(1-y-z)}DET_{y}SET_{z} RE₍₁₋ₓ₎HTₓX₅ (Formula 46)

wherein:

M²⁺ is one or more divalent metal elements;

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M¹⁺₃RE_{(1-x-y-z)}HTₓ DET_{y}SET_{z}X₆ (Formula 47)

wherein:

M¹⁺ is one or more monovalent metal elements;

RE is one or more rare earth elements;

X is one or more halogens;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M1¹⁺M2²⁺_{(1-y-z)}DET_{y}SET_{z} RE₍₁₋ₓ₎HTₓX₇ (Formula 48)

wherein:

M1¹⁺ is one or more monovalent metal elements;

M2²⁺ is one or more divalent metal elements;

RE is one or more rare earth elements;

HT is an element that provides a hole trap,

DET is a dopant that provides a relatively deep electron trap,

SET is a dopant that provides a relatively shallow electron trap, and

each of x, y, and z is at least 0.00001 and at most 0.09.

In an embodiment, each of x, y, and z has a value of at least 0.0002, at least 0.0005, or at least 0.001, and in another embodiment, each of x, y, and z has a value of at most 0.05, at most 0.04, or at most 0.03.

M²⁺_{(2-2y-2z)}DET_{y}SET_{z} RE₍₁₋ₓ₎HTₓX₇ (Formula 49)

wherein:

M²⁺ is one or more divalent metal elements;

RE is one or more rare earth elements;

X is one or more halogens;

HT is an element that provides a hole trap,

DET is a dopant that provides a relatively deep electron trap,

SET is a dopant that provides a relatively shallow electron trap, and

each of x, 2y, and 2z is at least 0.00001 and at most 0.09.

In an embodiment, each of x, 2y, and 2z has a value of at least 0.0002, at least 0.0005, or at least 0.001, and in another embodiment, each of x, 2y, and 2z has a value of at most 0.05, at most 0.04, or at most 0.03.

M¹⁺₃RE_{(2-2x-2y-2z)}HT₂ₓ DET_{2y}SET_{2z}X₉ (Formula 50)

wherein:

M¹⁺ is one or more monovalent metal elements;

RE is one or more rare earth elements;

X is one or more halogens;

HT is an element that provides a hole trap,

DET is a dopant that provides a relatively deep electron trap,

SET is a dopant that provides a relatively shallow electron trap, and

each of 2x, 2y, and 2z is at least 0.00001 and at most 0.09.

In an embodiment, each of 2x, 2y, and 2z has a value of at least 0.0002, at least 0.0005, or at least 0.001, and in another embodiment, each of 2x, 2y, and 2z has a value of at most 0.05, at most 0.04, or at most 0.03.

Exemplary compounds that can be modified in accordance with the above-referenced formulas include Ba₂GdCl₇, Ba₂YCl₇, BaBr₂, BaBrI, BaCl₂, BaF₂, BaGdCl₅, BaI₂, BaY₂F₈, BiF₃, CaF₂, CaI₂, Cs₂LiCeCl₆, Cs₂LiLuCl₆, Cs₂LiYBr₆, Cs₂LiYCl₆, Cs₂NaLaBr₆, Cs₂NaLuBr₆, Cs₂NaYBr₆, Cs₃CeCl₆, Cs₃Gd₂I₉, Cs₃LaBr₆, Cs₃Lu₂I₉, Cs₃LuI₆, CsBa₂I₅, CsCe₂Cl₇, CsGd₂F₇, CsI, CsY₂F₇, K₂CeBr₅, K₂LaCl₅, K₂YF₅, KLu₂F₇, KLuF₄, KYF₄, LaCeF₆, Li₃YCl₆, Lil, PbCl₂, Rb₂CeBr₅, LiCaAlF₆, Rb₂LiYBr₆, RbGd₂Br₇, SrBr₂, SrF₂, SrI₂, or the like, wherein x can range from 0 to 1. Each of the foregoing compounds may include a further dopant that is not provided with the chemical formula.

Many luminescent materials are disclosed herein and are to illustrate, and not limit, luminescent materials that can be used. After reading this specification, skilled artisans will appreciate that other luminescent materials may be used, wherein such other luminescent materials include a rare earth element as a principal constituent or as a dopant.

In the formulas above, each element that is designated by a valance state may be single element or a combination of elements having the same valance state. For example, M¹⁺ in a formula may be any one of the Group 1 elements (for example, Li₃, Na₃, K₃, Rb₃, or Cs₃), Ag, or could be a combination of such elements (for example, Cs₂Li, Cs₂Na, Rb₂Li, or the like). M²⁺ in a formula may be any one of the Group 2 elements (for example, Be₂, Mgₜ, Ca₂, Sr₂, or Ba₂), or could be a combination of such elements (for example, CaMg, CaSr, SrBa, or the like). A metal in a trivalent state may be a Group 13 element, a rare earth element in the trivalent state, or a combination thereof. For example, a luminescent material compound can include or a rare earth aluminum garnet, and M³⁺ may be used for both the rare earth element and Al. A metal in a tetravalent state may be Zr, Hf, or a combination thereof. Similar to the metal elements, X₂ in a formula may represent a single halogen (for example, F₂, Cl₂, Br₂, or I₂) or a combination of halogens (for example, ClBr, BrI, or the like). Thus, except for dopant(s), if any, the luminescent material can be a substantially single metal compound, a mixed metal compound, or a mixed halogen compound.

While many formulas are given above, such formulas are not comprehensive. In many of the formulas assume that the HTs are trivalent metal elements. When the HTs are divalent or monovalent metal elements, within the base compound, the substituted principal constituent for the HT may be different from the formulas above. For example, if HT is a divalent metal element, such HT may substitute for a principal constituent that is a divalent metal, as opposed to another principal constituent that is a trivalent metal element. Similarly, a DET that is a monovalent metal element may substitute for a principal constituent that is a monovalent metal element, as opposed to another principal constituent that is a divalent metal element.

Other elements that are not HTs, DETs, or SETs can be substituted for a principal constituent within a base compound. For example, Al can partly substitute for Si within silicate compounds.

HTs for the formulas above are based on elements as providing hole traps. When an interstitial site provides a hole trap, rather than an element, the subscripts for HT within the formulas can be taken to zero because an interstitial site that provides a hole trap will not appear within a chemical formula.

The formulas above have integer values for the subscripts of anions within base compounds. In another embodiment, the subscripts are not required to have integer values. The subscripts can deviate from an integer value, particularly when an element substituting for a principal constituent has a different valance state compared to such principal constituent. Thus, the subscripts for the anions are to provide general guidance on the anion content.

The luminescent material can be in the form of a single crystal material. The luminescent material in the form of a single crystal may be formed using a fusion zone technique, a Czochralski, a Bridgman, or an edge feed growth (EFG) technique. With the fusion zone technique, a solid material can be processed such that a crystal seed is in contact with one end of the solid, and a heat source causes a local region (portion of the solid) to become molten near the crystal. As the heat source moves away from the crystal, the molten portion becomes monocrystalline, and a new local region farther from the seed crystal becomes molten. The process is continued until the rest of the solid has become crystallized. The solid can be oriented in a vertical or horizontal direction during the process. The particular crystal growth methods as melting zone and floating zone are belonging to general notation known as fusion zone technique. The fusion zone technique may be able to incorporate a higher level of dopant than the Czochralski or Bridgman growth techniques, as volatilization or segregation of species may limit the ability of how much dopant will be in the crystal.

The luminescent material can be in the form of a polycrystalline material. Such materials can be formed using calcining, pressing, sintering, or any combination thereof. In an embodiment, a polycrystalline powder (obtained by hydrothermal method or by precipitation in alkaline solution or by vapor phase), the powder possibly being compacted with or without the use of a binder or thermally densified or assembled by a sol-gel method. In a further embodiment, the luminescent material can be a monocrystalline or polycrystalline fiber (obtained by micro-pulling down or by EFG), or thin film (obtained by CVD), or a polycrystalline glass-ceramic. The luminescent material may be incorporated in a host material that may be transparent, such as a glass or a plastic or a liquid or a crystal. The host material may be used to excite indirectly the scintillating compound.

Luminescent materials as previously described can be used in a variety of applications. Exemplary applications include gamma ray spectroscopy, isotope identification, Single Positron Emission Computer Tomography (SPECT) or Positron Emission Tomography (PET) scanner, x-ray imaging, oil well-logging detectors, and detecting the presence of radioactivity, a laser device, or an optical data storage device. The luminescent materials can be used for other applications, and thus, the list is merely exemplary and not limiting. A couple of specific applications are described below.

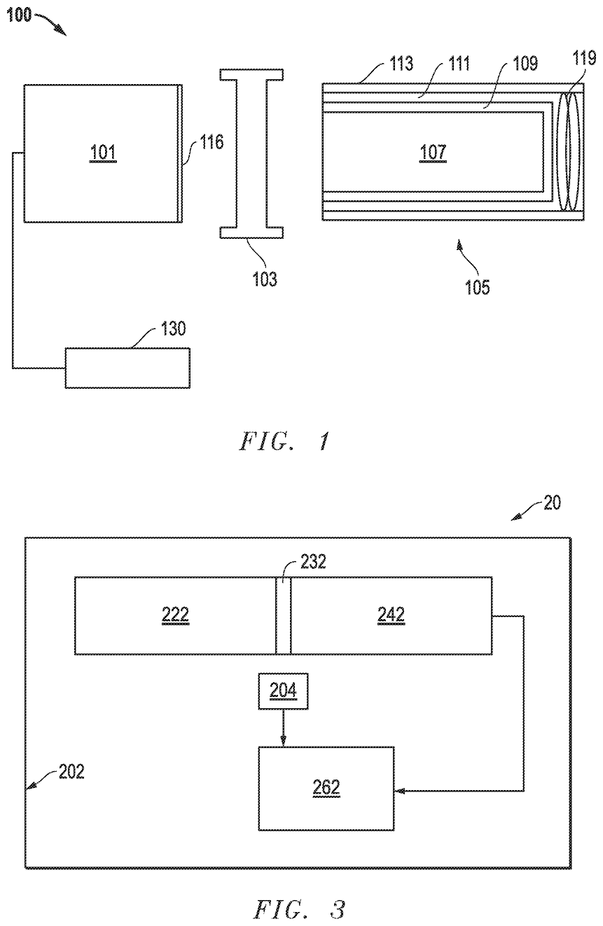

FIG. 1 illustrates an embodiment of a radiation detection apparatus 100 that can be used for gamma ray analysis, such as a Single Positron Emission Computer Tomography (SPECT) or Positron Emission Tomography (PET) analysis. In the embodiment illustrated, the radiation detection apparatus 100 includes a photosensor 101, an optical interface 103, and a scintillation device 105. Although the photosensor 101, the optical interface 103, and the scintillation device 105 are illustrated separate from each other, skilled artisans will appreciate that photosensor 101 and the scintillation device 105 can be coupled to the optical interface 103, with the optical interface 103 disposed between the photosensor 101 and the scintillation device 105. The scintillation device 105 and the photosensor 101 can be optically coupled to the optical interface 103 with other known coupling methods, such as the use of an optical gel or bonding agent, or directly through molecular adhesion of optically coupled elements.

The photosensor 101 may be a photomultiplier tube (PMT), a semiconductor-based photomultiplier, or a hybrid photosensor. A semiconductor-based photomultiplier can include an avalanche photodiode or a SiPM. The photosensor 101 can receive photons emitted by the scintillation device 105, via an input window 116, and produce electrical pulses based on numbers of photons that it receives. The photosensor 101 is electrically coupled to an electronics module 130. The electrical pulses can be shaped, digitized, analyzed, or any combination thereof by the electronics module 130 to provide a count of the photons received at the photosensor 101 or other information. The electronics module 130 can include an amplifier, a pre-amplifier, a discriminator, an analog-to-digital signal converter, a photon counter, a pulse shape analyzer or discriminator, another electronic component, or any combination thereof. The photosensor 101 can be housed within a tube or housing made of a material capable of protecting the photosensor 101, the electronics module 130, or a combination thereof, such as a metal, metal alloy, other material, or any combination thereof.

The scintillation device 105 includes a scintillator 107 that can include any one of the luminescent materials previously described. The scintillator 107 is substantially surrounded by a reflector 109. In one embodiment, the reflector 109 can include polytetrafluoroethylene (PTFE), another material adapted to reflect light emitted by the scintillator 107, or a combination thereof. In an illustrative embodiment, the reflector 109 can be substantially surrounded by a shock absorbing member 111. The scintillator 107, the reflector 109, and the shock absorbing member 111 can be housed within a casing 113.

The scintillation device 105 includes at least one stabilization mechanism adapted to reduce relative movement between the scintillator 107 and other elements of the radiation detection apparatus 100, such as the optical interface 103, the casing 113, the shock absorbing member 111, the reflector 109, or any combination thereof. The stabilization mechanism may include a spring 119, an elastomer, another suitable stabilization mechanism, or a combination thereof. The stabilization mechanism can be adapted to apply lateral forces, horizontal forces, or a combination thereof, to the scintillator 107 to stabilize its position relative to one or more other elements of the radiation detection apparatus 100.

As illustrated, the optical interface 103 is adapted to be coupled between the photosensor 101 and the scintillation device 105. The optical interface 103 is also adapted to facilitate optical coupling between the photosensor 101 and the scintillation device 105. The optical interface 103 can include a polymer, such as a silicone rubber, that is polarized to align the reflective indices of the scintillator 107 and the input window 116. In other embodiments, the optical interface 103 can include gels or colloids that include polymers and additional elements.

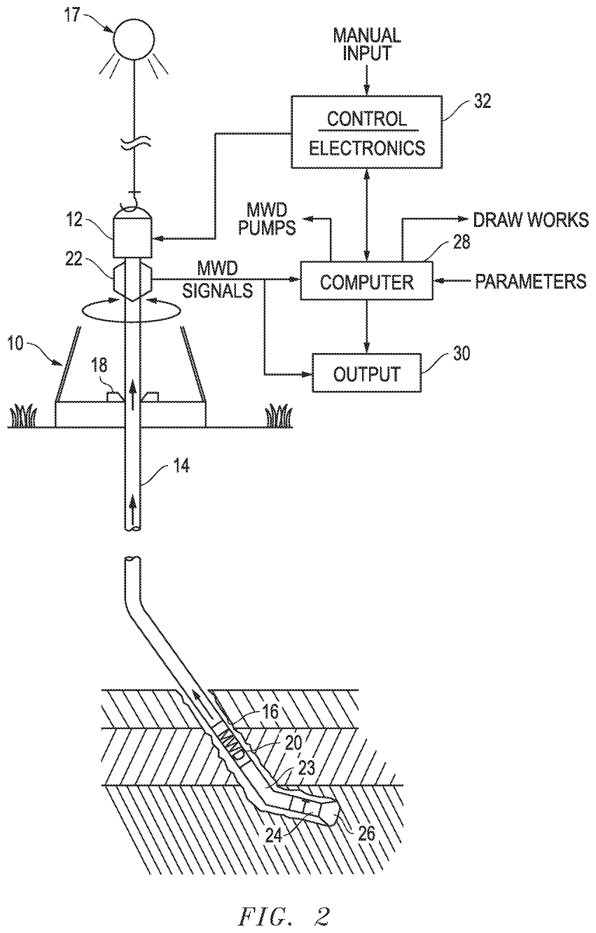

The luminescent material can be used in a well logging application. FIG. 2 includes a depiction of a drilling apparatus 10 includes a top drive 12 connected to an upper end of a drill string 14 that is suspended within a well bore 16 by a draw works 17. A rotary table, including pipe slips, 18 can be used to maintain proper drill string orientation in connection with or in place of the top drive 12. A downhole telemetry measurement and transmission device 20, commonly referred to as a measurement-while-drilling (MWD) device, is part of a downhole tool that is connected to a lower end of the drill string 14. The MWD device transmits drilling-associated parameters to the surface by mud pulse or electromagnetic transmission. These signals are received at the surface by a data receiving device 22. The downhole tool includes a bent section 23, a downhole motor 24, and a drill bit 26. The bent section 23 is adjacent the MWD device for assistance in drilling an inclined well bore. The downhole motor 24, such as a positive-displacement-motor (PDM) or downhole turbine, powers the drill bit 26 and is at the distal end of the downhole tool.

The downhole signals received by the data reception device 22 are provided to a computer 28, an output device 30, or both. The computer 28 can be located at the well site or remotely linked to the well site. An analyzer device can be part of the computer 28 or may be located within the downhole tool near the MWD device 20. The computer 28 and analyzer device can include a processor that can receive input from a user. The signals are also sent to an output device 30, which can be a display device, a hard copy log printing device, a gauge, a visual audial alarm, or any combination thereof. The computer 28 is operatively connected to controls of the draw works 17 and to control electronics 32 associated with the top drive 12 and the rotary table 18 to control the rotation of the drill string and drill bit. The computer 28 may also be coupled to a control mechanism associated with the drilling apparatus's mud pumps to control the rotation of the drill bit. The control electronics 32 can also receive manual input, such as a drill operator.

FIG. 3 illustrates a depiction of a portion of the MWD device 20 within the downhole tool 16. The MWD device 20 includes a housing 202, a temperature sensor 204, a scintillator 222, an optical interface 232, a photosensor 242, and an analyzer device 262. The housing 202 can include a material capable of protecting the scintillator 222, the photosensor 242, the analyzer device 262, or a combination thereof, such as a metal, metal alloy, other material, or any combination thereof. The scintillator 222 can include one or more of the luminescent materials previously described. The temperature sensor 204 is located adjacent to the scintillator 222, the photosensor 242, or both. The temperature sensor 204 can include a thermocouple, a thermistor, or another suitable device that is capable of determining the temperature within the housing over the normal operating temperature of the MWD device 20. A radiation detection apparatus includes the scintillation crystal 222 that is optically coupled to the photosensor 242 that is coupled to the analyzer device 262.

Luminescent materials as described in accordance with the concepts described herein have an unusually low average departure from perfect linearity, particularly for energies less than 50 keV, such as in a range of 5 keV to 20 keV. The luminescent material can include a rare earth halide, a HT, a DET, and a SET. A ratio of the concentrations of the DET:SET can be tailored to achieve the good linearity performance over a desired energy range.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Luminescent materials as described in accordance with the concepts described herein have an unusually low average departure from perfect linearity, particularly for energies less than 50 keV, such as in a range of 5 keV to 20 keV. The luminescent material can include a rare earth halide, a HT, a DET, and a SET. A ratio of the concentrations of the DET:SET can be tailored to achieve the good linearity performance over a desired energy range.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the embodiments as listed below.

Embodiment 1. A luminescent material comprising: an element or an interstitial site that provides a hole trap in the luminescent material; a first dopant that provides a first electron trap in the luminescent material; and a second dopant that provides a second electron trap in the luminescent material, wherein the second dopant is a relatively shallower electron trap as compared to the first dopant, wherein a ratio of the first dopant to the second dopant in the luminescent material is selected so that luminescent material has a lower average value for a departure from perfect linearity in a range of 5 keV to 20 keV that is less as compared to a different luminescent material that is doped with only the element and first dopant or only the element and the second dopant, and wherein the luminescent material is not a rare earth halide.

Embodiment 2. The luminescent material of Embodiment 1, wherein a ratio of the first dopant to the second dopant in the luminescent material is in a range of 10:1 to 100:1 on an atomic basis.

Embodiment 3. The luminescent material of Embodiment 1 or 2, wherein the average value for the departure from perfect linearity (DFPL_{average}) is determined by:

$$DFP {L}_{a v erage} = \frac{{{\int }^{{E}_{upper}}}_{{E}_{lower}} DFPL ( {E}_{i} ) \cdot {dE}_{i}}{{E}_{upper} - {E}_{lower}} ,$$

where

DFPL(Ei) is DFPL at energy Eᵢ;

Eᵤₚₚₑᵣ is 20 keV; and

E_{lower} is 5 keV.

Embodiment 4. A luminescent material comprising: an element or an interstitial site that provides a hole trap in the luminescent material; a first dopant that provides a first electron trap in the luminescent material; and a second dopant that provides a second electron trap in the luminescent material, wherein the second dopant is a relatively shallower electron trap as compared to the first electron trap, wherein a ratio of the first dopant to the second dopant in the luminescent material is in a range of 10:1 to 100:1 on an atomic basis, and wherein the luminescent material is not a rare earth halide.

Embodiment 5. The luminescent material of any one of Embodiments 2 to 4, wherein the ratio of the first dopant to the second dopant is at least 3:1, at least 15:1, at least 20:1, or at least 30:1 on an atomic basis.

Embodiment 6. The luminescent material of any one of Embodiments 2 to 5, wherein the ratio of the first dopant to the second dopant is at most 100:1, at most 95:1, at most 80:1, or at most 70:1 on an atomic basis.

Embodiment 7. The luminescent material of any one of Embodiments 2 to 4, wherein the ratio of the first dopant to the second dopant is in a range of 3:1 to 100:1, 15:1 to 95:1, 20:1 to 80:1, or 30:1 to 70:1 on an atomic basis.

Embodiment 8. The luminescent material of any one of Embodiments 1 to 7, wherein the luminescent material includes a base compound having a minimum energy level of a conduction band that is closer to an ionization energy of the second dopant than to an ionization energy of the first dopant.

Embodiment 9. The luminescent material of any one of Embodiments 1 to 7, wherein the luminescent material includes a base compound having a bandgap energy, wherein an energy level difference between a minimum energy level of a conduction band of the base compound and an ionization energy of the second dopant is at most 10% of the bandgap energy.

Embodiment 10. The luminescent material of any one of Embodiments 1 to 7, wherein the luminescent material includes a base compound having a bandgap energy, wherein a minimum energy level difference between an energy level of a conduction band of the base compound and an ionization energy of the first dopant is greater than 10% of the bandgap energy.

Embodiment 11. The luminescent material of any one of Embodiments 1 to 7, wherein the luminescent material includes a base compound, wherein an energy level difference between a minimum energy level of a conduction band of the base compound and an ionization energy of the second dopant is at most 0.3 eV.

Embodiment 12. The luminescent material of any one of Embodiments 1 to 7, wherein the luminescent material includes a base compound, wherein an energy level difference between a minimum energy level of a conduction band of the base compound and an ionization energy of the first dopant is greater than 0.3 eV.

Embodiment 13. The luminescent material of any one of Embodiments 1 to 12, wherein the element or the first or second dopant is a rare earth element or Bi.

Embodiment 14. The luminescent material of any one of Embodiments 1 to 13, wherein the element or the first or second dopant is Ce, Pr, Sm, or Tb.

Embodiment 15. The luminescent material of any one of Embodiments 1 to 14, wherein the second dopant comprises Ca or Sr.

Embodiment 16. The luminescent material of Embodiment 14, wherein the first dopant includes a Group 1 element, Mg, or Ba, and the second dopant includes Ca or Sr.

Embodiment 17. The luminescent material of any one of Embodiments 1 to 12, wherein the element or the first or second dopant is Eu or Yt.

Embodiment 18. The luminescent material of Embodiment 16, wherein the interstitial site provides the hole trap.

Embodiment 19. The luminescent material of any one of Embodiments 1 to 18, wherein the luminescent material comprises a silicate.

Embodiment 20. The luminescent material of Embodiment 19, wherein the silicate is an oxyorthosilicate.

Embodiment 21. The luminescent material of Embodiment 19, wherein the silicate is a pyrosilicate.

Embodiment 22. The luminescent material of any one of Embodiments 1 to 18, wherein the luminescent material comprises a metal oxide.

Embodiment 23. The luminescent material of Embodiment 22, wherein the luminescent material comprises a metal-aluminum-oxygen compound, wherein the metal is different from aluminum.

Embodiment 24. The luminescent material of Embodiment 23, wherein the metal-aluminum-oxygen compound comprises a metal aluminate.

Embodiment 25. The luminescent material of Embodiment 23 or 24, wherein the metal-aluminum-oxygen compound comprises a metal aluminum garnet.

Embodiment 26. The luminescent material of Embodiment 22, wherein the metal oxide is a perovskite.

Embodiment 27. The luminescent material of any one of Embodiments 22 to 26, wherein the metal oxide does not include B, Si, P, S, or a halide.

Embodiment 28. The luminescent material of any one of Embodiments 1 to 14, wherein the luminescent material comprises a metal-boron-oxygen compound.

Embodiment 29. The luminescent material of Embodiment 28, wherein the metal-boron-oxygen compound comprises a metal borate.

Embodiment 30. The luminescent material of Embodiment 25, wherein the metal-boron-oxygen compound comprises a metal oxyborate.

Embodiment 31. The luminescent material of any one of Embodiments 1 to 17, wherein the luminescent material comprises a metal-phosphorus-oxygen compound.

Embodiment 32. The luminescent material of Embodiment 31, wherein the metal-phosphorus-oxygen compound comprises a metal phosphite.

Embodiment 33. The luminescent material of Embodiment 31, wherein the metal-phosphorus-oxygen compound comprises a metal phosphate.

Embodiment 34. The luminescent material of Embodiment 31, wherein the metal-phosphorus-oxygen compound comprises a Group 2 metal phosphate halide.

Embodiment 35. The luminescent material of any one of Embodiments 1 to 17, wherein the luminescent material comprises a metal-oxygen-sulfur compound.

Embodiment 36. The luminescent material of Embodiment 35, wherein the metal-oxygen-sulfur compound comprises a metal oxysulfide.

Embodiment 37. The luminescent material of any one of Embodiments 1 to 17, wherein the luminescent material comprises a metal-oxygen-halogen compound.

Embodiment 38. The luminescent material of Embodiment 37, wherein the metal-oxygen-halogen compound comprises a metal oxyhalide.

Embodiment 39. The luminescent material of any one of Embodiments 1 to 17, wherein the luminescent material comprises a metal halide.

Embodiment 40. The luminescent material of Embodiment 39, wherein, except for the element and the first and second dopants, the metal halide is a single metal halide.

Embodiment 41. The luminescent material of Embodiment 39, wherein, except for the first and second dopants, the metal halide is a single metal halide.

Embodiment 42. The luminescent material of Embodiment 39, wherein, except for the first and second dopants the metal halide is a mixed metal halide.

Embodiment 43. The luminescent material of any one of Embodiments 39 to 42, wherein the metal halide is a mixed halogen metal halide.

Embodiment 44. The luminescent material of any one of Embodiments 39 to 43, wherein the base compound that is a rare earth halide or an elpasolite.

Embodiment 45. A radiation detection apparatus comprising: a material comprising the luminescent material of any one of Embodiments 1 to 43; and a photosensor configured to receive scintillating light from the luminescent material.

Embodiment 46. The radiation detection apparatus of Embodiment 45, wherein the radiation detection apparatus comprises a medical imaging apparatus, a well logging apparatus, or a security inspection apparatus.

Embodiment 47. A positron emission tomography scanner comprising the luminescent material of any one of Embodiments 1 to 44.

Embodiment 48. A laser device comprising the luminescent material of any one of Embodiments 1 to 41.

Embodiment 49. An optical data storage device comprising the luminescent material of any one of Embodiments 1 to 44.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and apparatuses that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A luminescent material comprising:
an element or an interstitial site that provides a hole trap in the luminescent material;
a first dopant that provides a first electron trap in the luminescent material; and
a second dopant that provides a second electron trap in the luminescent material,
wherein the second dopant is a relatively shallower electron trap as compared to the first dopant,
wherein a ratio of the first dopant to the second dopant in the luminescent material is selected so that luminescent material has a lower average value for a departure from perfect linearity in a range of 5 keV to 20 keV that is less as compared to a different luminescent material that is doped with only the element and first dopant or only the element and the second dopant, and wherein the luminescent material is not a rare earth halide.

2. The luminescent material of claim 1, wherein a ratio of the first dopant to the second dopant in the luminescent material is in a range of 10:1 to 100:1 on an atomic basis.

3. The luminescent material of claim 1, wherein the average value for the departure from perfect linearity (DFPL_{average}) is determined by:
$$DFP {L}_{a v erage} = \frac{{{\int }^{{E}_{upper}}}_{{E}_{lower}} DFPL ( {E}_{i} ) \cdot {dE}_{i}}{{E}_{upper} - {E}_{lower}} ,$$
where
DFPL(Ei) is DFPL at energy Eᵢ;
Eᵤₚₚₑᵣ is 20 keV; and
E_{lower} is 5 keV.

4. A luminescent material comprising:
an element or an interstitial site that provides a hole trap in the luminescent material;
a first dopant that provides a first electron trap in the luminescent material; and
a second dopant that provides a second electron trap in the luminescent material,
wherein the second dopant is a relatively shallower electron trap as compared to the first electron trap,
wherein a ratio of the first dopant to the second dopant in the luminescent material is in a range of 10:1 to 100:1 on an atomic basis, and wherein the luminescent material is not a rare earth halide.

5. The luminescent material of claim 4, wherein the ratio of the first dopant to the second dopant is in a range of 15:1 to 95:1 on an atomic basis.

6. The luminescent material of claim 4, wherein the element or the first or second dopant is a rare earth element or Bi.

7. The luminescent material of claim 4, wherein the element or the first or second dopant is Ce, Pr, Sm, or Tb.

8. The luminescent material of claim 4, wherein the luminescent material includes a base compound having a minimum energy level of a conduction band that is closer to an ionization energy of the second dopant than to an ionization energy of the first dopant.

9. The luminescent material of claim 4, wherein the luminescent material includes a base compound having a bandgap energy, wherein an energy level difference between a minimum energy level of a conduction band of the base compound and an ionization energy of the second dopant is at most 10% of the bandgap energy.

10. The luminescent material of claim 4, wherein the luminescent material includes a base compound having a bandgap energy, wherein a minimum energy level difference between an energy level of a conduction band of the base compound and an ionization energy of the first dopant is greater than 10% of the bandgap energy.

11. The luminescent material of claim 4, wherein the luminescent material includes a base compound, wherein an energy level difference between a minimum energy level of a conduction band of the base compound and an ionization energy of the second dopant is at most 0.3 eV.

12. The luminescent material of claim 4, wherein the luminescent material includes a base compound, wherein an energy level difference between a minimum energy level of a conduction band of the base compound and an ionization energy of the first dopant is greater than 0.3 eV.

13. A luminescent material comprising:
an element or an interstitial site that provides a hole trap in the luminescent material;
a first dopant that provides a first electron trap in the luminescent material; and
a second dopant that provides a second electron trap in the luminescent material,
wherein the second dopant is a relatively shallower electron trap as compared to the first electron trap, wherein the first dopant includes a Group 1 element, Mg, or Ba, and the second dopant includes Ca or Sr, and wherein a ratio of the first dopant to the second dopant in the luminescent material is in a range of 10:1 to 100:1 on an atomic basis, and wherein the luminescent material is not a rare earth halide.

14. The luminescent material of claim 13, wherein the element or the first or second dopant is Eu or Yt.

15. The luminescent material of claim 13, wherein the luminescent material comprises a metal-phosphorus-oxygen compound selected from the group comprising a metal phosphite, a metal phosphate, and a Group 2 metal phosphate halide.

16. The luminescent material of claim 4, wherein the ratio of the first dopant to the second dopant is in a range of 20:1 to 80:1 on an atomic basis

17. The luminescent material of claim 13, wherein the luminescent material comprises a metal-boron-oxygen compound selected from the group comprising metal borate and metal oxyborate.

18. The luminescent material of claim 13, wherein the luminescent material comprises a metal-aluminum-oxygen compound, wherein the metal is different from aluminum.

19. The luminescent material of claim 18, wherein the metal-aluminum-oxygen compound comprises a metal aluminate.

20. The luminescent material of claim 18, wherein the metal-aluminum-oxygen compound comprises a metal aluminum garnet.
